(19) United States
(12) Patent Application Publication
(10) Pub. No.: US 2006/0198307 A1
(43) Pub. Date: Sep. 7, 2006

(54) SYSTEM AND METHOD FOR CONTROLLING A SERVICE TO USE A RESOURCE

(76) Inventor: Cheng-Yin Shen, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,889

(22) Filed: Dec. 8, 2005

(30) Foreign Application Priority Data
Dec. 24, 2004 (TW) 093140415

(51) Int. Cl. H04L 12/26; G01R 31/08; G06F 11/00

(52) U.S. Cl. 370/236.1

(57) ABSTRACT

A system for controlling a service to use a resource is disclosed. The system includes: an active bitmap (130) for recording a plurality of bits, each of which corresponds to a resource and has a certain value; an obtaining module (131) for obtaining the active bitmap to check a value of a bit corresponding to the resource; a judging module (132) for determining whether the service can use the resource according to the value of the bit; and a message returning module (133) for returning a message denoting whether the service succeeds in using the resource. A related method is also disclosed.

### FIELD OF THE INVENTION

The present invention relates to a system and method for controlling a service to use a resource.

### DESCRIPTION OF RELATED ART

In computer systems, there are many resources, such as CPUs, memories, hard disks, CD/DVD ROMs, tape devices and so on. Each computer system provides a large number of services for users. During the period of running the services, resources corresponding to the services are required. Before a service begins to use a corresponding resource, the computer system generally needs to generate a request for the service to use the resource.

Some resources can be shared by more than one service. For example, a file stored in a hard disk of an application server is such a resource, and various services can share the file. When a user is copying the file from the hard disk and meanwhile another user is deleting the file from the hard disk, a problem occurs, causing that the user cannot copy the file safely.

Therefore, what is needed is a method for controlling a service to use a resource, in which the service can use the resource safely.

### SUMMARY OF INVENTION

A system for controlling a service to use a resource is provided. The system includes: an active bitmap for recording a plurality of bits, each bit corresponding to a resource and having a certain value; an obtaining module for obtaining the active bitmap to check a value of a bit corresponding to the resource, and a judging module for determining whether the service can use the resource according to the value of the bit.

A method for controlling a service to use a resource is provided. The method includes the steps of: starting the service; obtaining an active bitmap and checking a value of a bit corresponding to the resource; determining whether the service can use the resource according to the value of the bit; using the resource and setting the value of the bit to “1” if the value of the bit is “0;” setting the value of the bit to “0” and releasing the active bitmap when the service finishes using the resource; and returning a truth message showing that the service uses the resource successfully.

Other advantages and novel features of the embodiments will be drawn from the following detailed description with reference to the attached drawings, in which:

### BRIEF DESCRIPTION OF DRAWINGS

FIG. 1 is a schematic diagram of an application environment and hardware configuration of a system for controlling a service to use a resource in a computer system in accordance with a preferred embodiment; and

FIG. 2 is a flowchart of a preferred method for controlling a service to use a resource by utilizing the system of FIG. 1.

### DETAILED DESCRIPTION

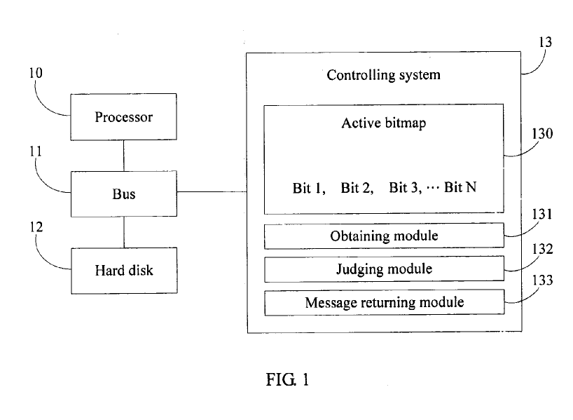

FIG. 1 is a schematic diagram of an application environment and hardware configuration of a system for controlling a service to use a resource in a computer system (hereinafter, “the controlling system 13”) in accordance with a preferred embodiment. The controlling system 13 is generally executed in a computer, and is connected with a processor 10 and a hard disk 12 through a bus 11. The processor 10 is used for processing instructions from users and transmitting the instructions to the hard disk 12 via the bus 11. The hard disk 12 is used for storing resources. The resources may be software resources or hardware resources, for example, a file stored in the hard disk 12. The controlling system 13 is used for controlling a service to use the resources stored in the hard disk 12. The controlling system 13 typically includes an active bitmap 130, an obtaining module 131, a judging module 132, and a message returning module 133. The active bitmap 130 is used for recording a plurality of bits, which are illustrated by Bit1, Bit2, Bit3, . . . , Bit N. Each bit corresponds to a resource, and has a certain value. When a resource is unoccupied, the value of a corresponding bit is “0,” and when the resource is occupied by any other service, the value of the bit is “1.” The obtaining module 131 is used for obtaining the active bitmap 130 to check a value of a bit of a resource, and releasing the active bitmap 130 when a service finishes using the resource. The judging module 132 is used for determining whether the service can use the resource according to the value of the bit, and setting the value of the bit to “1” when the service is using the resource. When the service finishes using the resource, the judging module 132 sets the value of the bit to “0.” The message returning module 133 is used for returning a message denoting whether the service succeeds in using the resource. For example, the message returning module 123 returns a truth message when the service uses the resource successfully, or returns a false message when the service cannot use the resource.

The implementation of the system can be better illustrated by an example. When a user gives an instruction of viewing a file, the processor 11 processes the instruction and transmits the instruction to the hard disk 12 via the bus 11. In this example, the file is a resource, and viewing the file by the user can be regarded as a service. If the file is being viewed by other users, the value of a bit corresponding to the file in the active bitmap 130 is “1.” Therefore, the judging module 132 determines that the user cannot view the file. If the file is not being viewed by any user, the value of the bit corresponding to the file is “0.” Then, the judging module 132 determines that the user can view the file.

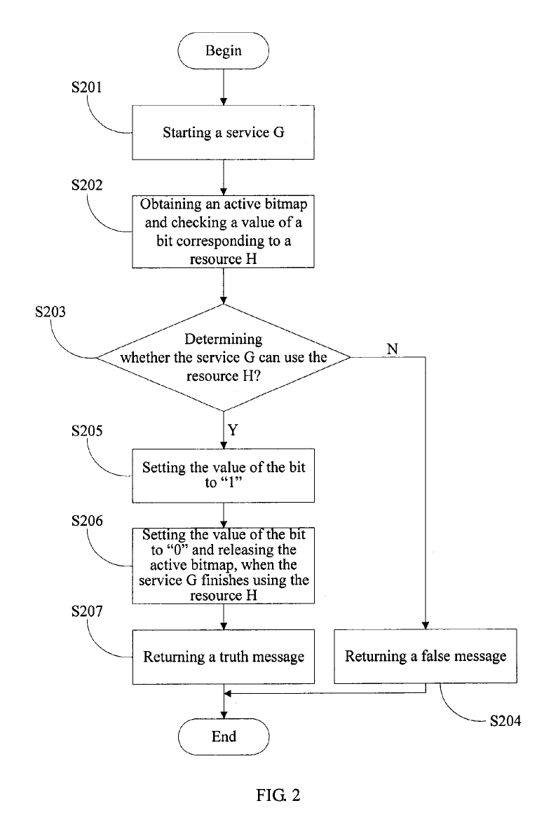

FIG. 2 is a flowchart of a preferred method for controlling a service to use a resource by utilizing the system of FIG. 1. In step S201, when a user gives an instruction of controlling a service G to use a resource H, the processor 10 processes the instruction and transmits the instruction to the hard disk 12 via the bus 11. Then, the service G is started. In step S202, the obtaining module 131 obtains the active bitmap 130 and checks a value of a bit corresponding to the resource H. In step S203, the judging module 132 determines whether the service G can use the resource H according to the value of the bit. If the value is “1” which means the resource H is occupied, in step S204, the message returning module 133 returns a false message denoting that the service G cannot use the resource H. Otherwise, if the value is “0,” which means the resource H is unoccupied, in step S205, the judging 132 sets the value of the bit to “1” in order that any other service cannot use the resource H when the service G is using the resource H. In step S206, the judging module 132 sets the value of the bit to “0” and the obtaining module 131 releases the active bitmap 130, when the service G finishes using the resource H. In step S207, the message returning module 133 returns a truth message denoting that the service G uses the resource H successfully.

Although the present invention has been specifically described on the basis of a preferred embodiment and preferred method, the invention is not to be construed as being limited thereto. Various changes or modifications may be made to the embodiment and method without departing from the scope and spirit of the invention.

What is claimed is:

1. A system for controlling a service to use a resource, the system comprising:
an active bitmap for recording a plurality of bits, each bit corresponding to a resource and having a certain value;
an obtaining module for obtaining the active bitmap to check a value of a bit corresponding to the resource, and
a judging module for determining whether the service can use the resource according to the value of the bit.

2. The system according to claim 1, further comprising a message returning module for returning a message denoting whether the service succeeds in using the resource.

3. The system according to claim 2, wherein the message returning module returns a truth message when the service uses the resource successfully, or returns a false message when the service cannot use the resource.

4. The system according to claim 1, wherein the value of the bit is “0” when the resource is unoccupied, and the value of the bit is “1” when the resource is occupied by any other service.

5. The system according to claim 1, wherein the obtaining module is further for releasing the active bitmap when the service finishes using the resource.

6. The system according to claim 1, wherein the judging module is further for setting the value of the bit to “1” when the service is using the resource, and setting the value of the bit to “0” when the service finishes using the resource.

7. A computer-based method for controlling a service to use a resource, the method comprising the steps of:
starting the service;
obtaining an active bitmap and checking a value of a bit corresponding to the resource;
determining whether the service can use the resource according to the value of the bit;
using the resource and setting the value of the bit to “1” if the value of the bit is “0;”
setting the value of the bit to “0” and releasing the active bitmap when the service finishes using the resource; and
returning a truth message showing that the service uses the resource successfully.

8. The method according to claim 7, further comprising the step of:
returning a false message denoting that the service cannot use the resource, if the value of the bit is “1”.

9. The method according to claim 7, wherein the value of the bit is “0” when the resource is unoccupied, and the value of the bit is “1” when the resource is occupied by any other service.
